(19) United States
(12) Patent Application Publication
(10) Pub. No.: US 2008/0122673 A1
(43) Pub. Date: May 29, 2008

(54) Gain and linearity matching for multi-channel time-interleaved pipelined ADC

(76) Inventor: Kenneth C. Dyer, Davis, CA (US)

Correspondence Address: LUMEN PATENT FIRM, INC., 2345 YALE STREET, SECOND FLOOR, PALO ALTO, CA, 94306, US

(21) Appl. No.: 11/607,133

(22) Filed: Nov. 29, 2006

(51) Int. Cl. H03M 1/12

(52) U.S. Cl. 341/155

(57) ABSTRACT

By constructing the stages of a pipelined analog to digital converter (ADC) such that they are in close proximity while sharing a voltage reference, bias, and power supply, the linearity of the ADC's will match since the relatively large devices that now dictate the ADC linearity are in close proximity to one another. Supply and reference IR drops are also matched reducing gain and linearity mismatch. Based on this, it is possible to construct a shared multi-channel ADC with exceptionally good matching of gain, phase, and linearity without additional hardware to match the channels.

### FIELD

The invention relates to analog to digital converters, and, more particularly, to gain and linearity matching for multi-channel time-interleaved pipelined (analog to digital converters) ADC's.

### BACKGROUND

Time-interleaved, multi-channel ADC's are sensitive to mismatches between the channels. The key mismatches are in the gain, offset and phase of the ADC channels. Engineers have noted that if the linearity of the ADC's are mismatched, then the ADC performance is further impaired. Mismatches in these parameters reduce the performance of the ADC.

Prior art techniques for fixing the mismatch assumed that the gain mismatches between the channels were random. The prior art techniques including trimming or background calibration addressed the gain mismatch between the channels. Another prior art technique incorporated a digital filter to reduce the impact of the mismatches at the cost of signal bandwidth. The prior art has not addressed a technique to match the linearity of the multiple channels that comprise the time-interleaved ADC. What is needed is an multi-channel ADC that matches both the linearity and the gain between the channels of the ADC.

### SUMMARY

A time-interleaved multi-channel pipelined analog to digital converter is described with a shared voltage reference generator, a shared bias network, and a shared power grid.

### BRIEF DESCRIPTION OF DRAWINGS

FIG. 1 shows an example of a multi-channel ADC with a shared reference voltage.

FIG. 2 shows an example of a multi-channel ADC with a shared bias.

FIG. 3 shows an example of a multi-channel ADC with a shared power source.

FIG. 4 shows an example of an output spectrum for a two channel interleaved ADC with gain mismatch.

FIG. 5 shows an example of a collected data for a FFT of a time-interleaved ADC.

### DESCRIPTION

The gain of a plurality of pipelined ADC's is matched by matching the primary physical and electrical mechanisms of the gain and linearity mismatch between the two channels. With two-interleaved ADC channels, for example, resources such as references, power, and bias can be shared and distributed centrally throughout the ADC, reducing channel gain and linearity mismatches. This eliminates the requirement of trimming, calibration or a digital filter thus reducing area and power when compared to the prior art.

For the case of a multi-channel time-interleaved pipelined ADC, sharing the ADC reference voltage, power-grid and bias reduces the effect of gain and linearity matching between the adjacent ADC channels. By constructing the circuit elements that dictate linearity in the multiple channels in close proximity while matching the IR drops in the reference and power-grid, the linearity matching between the channels can be improved. The end result is a multi-channel time-interleaved ADC that operates architecturally without the need for external gain or linearity mismatch correction.

By constructing corresponding stages of the ADC such that they are in close proximity while sharing references, bias and power supply, the linearity of the ADC's will match, since the relatively large devices that now dictate the ADC linearity are in close proximity to one another. Supply and input-signal dependent reference IR drops are also matched reducing gain and linearity mismatch. Based on this, it is possible to construct a shared multi-channel ADC with exceptionally good matching of gain and linearity without additional hardware to match the multiple channels.

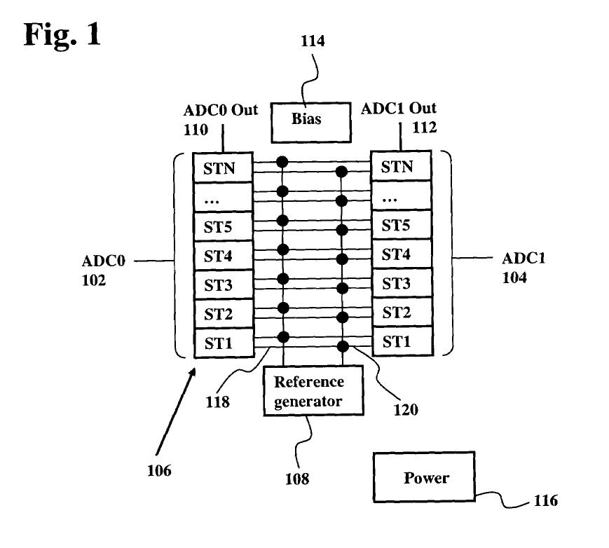

FIG. 1 shows an example of a dual-channel time-interleaved pipelined ADC with a shared reference voltage. The ADC has two ADC channels, ADC0 102 and ADC1 104, a reference voltage generator 108, power 116, and bias 114. Each of the channels 102, 104 comprises n stages 106, which are shown and labeled as the range from ST1 to STN. The channel outputs of ADC0 output 110 and ADC1 output 112 are shown, as are the two reference voltage ladders 118, 120. The two outputs 110, 112 are time interleaved to form the final digital result.

Each channel 102, 104 operates at half the sample rate. The combined sample rate of the two channels is twice that of any one single channel. The performance of this type of ADC is reduced when the channel gains do not match each other. To match the gain of the two ADC channels 102, 104, the ADC voltage references are shared between the two channels with the two reference voltage ladders 118, 120 as shown in FIG. 1. When the ADC operates, the stages draw current from the references 118, 120. This affects both the gain and the linearity of the two ADC channels 102, 104. Since the references 118, 120 are shared, they are matched between the two ADC channels 102, 104, even in the case of IR drops in the reference distribution.

Two channels are used for the example shown in FIG. 1. Of course it is possible to build a multi-channel time-interleaved pipelined ADC with a plurality of channels (four, eight, etc. for example). Where the multi-channel ADC has a sampling frequency of F and has N channels, each channel operates at a frequency of F/N. The number of references 118, 120 can be one or more, but two is the most likely number. When using N>2, the references of the parallel ADC stages can similarly be strapped as shown in FIG. 1 with the horizontal reference lines extending to neighboring ADC channels to the left and right of those shown in FIG. 1. Alternatively the time-interleaved ADCs could be stacked on top of each other with the references shared up and down the die stack. The ADCs would desirably be coincident with each other.

Each pipeline stage 106 consists of switched-capacitor stage that samples the reference 118, 120 and the output of the previous stage 106 (except for ST1). The number of stages are determined by the desired resolution of the pipelined ADC. This technique works for any number of stages 106. The critical analog portions of the stages 106 are placed as close as possible to each-other in the circuit board layout in an effort to match their dynamic performance. This reduces the effect of linearity mismatch due to the correlation of the transistor performance with the corresponding channel's stage 106. For example, ST1 on ADC0 102 matches ST1 on ADC1 104.

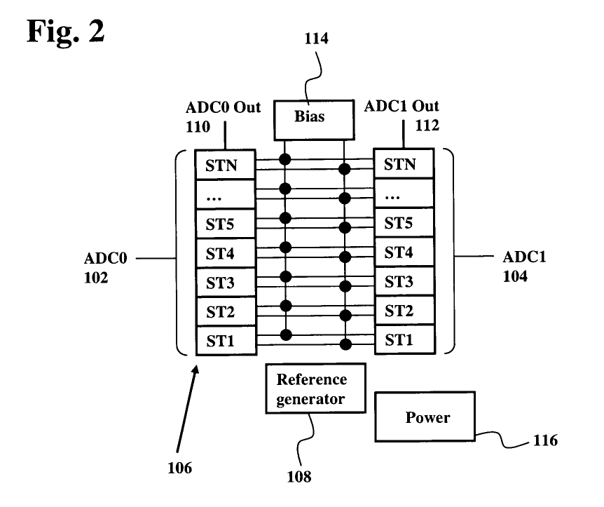

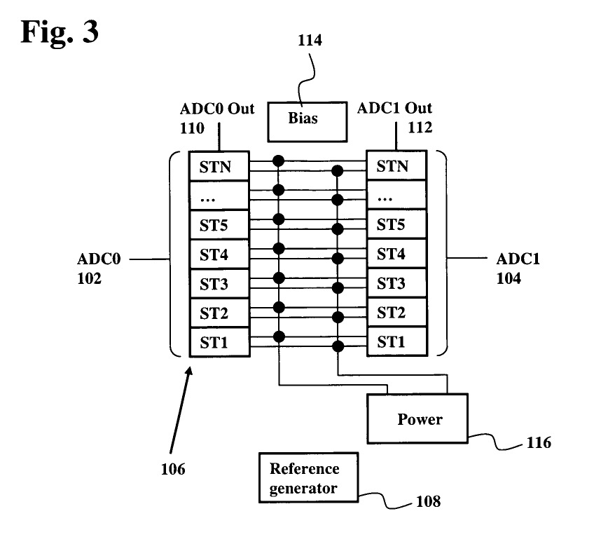

FIGS. 2 and 3 shown examples of a dual-channel time-interleaved pipelined ADC with a shared bias and shared power, respectively. The shared reference voltage, bias, and power shown in FIGS. 1-3 are active at the same time. The have been shown on three separate figures for clarity. The bias network is shared between the two ADC channels to allow better matching of the performance of the adjacent amplifiers. The sharing of the power-grid is to match any supply dependent effects on the linearity of the neighboring ADC channels.

A basic discussion on pipelined ADC gain and linearity follows. An ADC transfer function is given by:

$$Code = \frac{{2}^{N - 1}}{{V}_{ref}} \cdot ( {V}_{i n} + {AV}_{i n}^{2} + {BV}_{i n}^{3} + {CV}_{i n}^{4} + … )$$

where:
N=Number of bits
V_{ref}=the ADC reference voltage to which the input signal is compared
Vᵢₙ=Input voltage (analog) which ranges between +V_{ref} and −V_{ref}
Code=Signed output of the ADC which ranges from −2̂N−1 to 2̂N−1
A, B, C . . . are coefficients that represent the nonlinearity of the ADC. These coefficients are small and non-zero in all practical ADC's.

The gain of an ADC can be determined by taking the derivative of the ADC transfer function, above, with respect to the input:

$$Gain = \frac{{2}^{N - 1}}{{V}_{ref}} \cdot ( 1 + 2 {AV}_{i n} + 3 {BV}_{i n}^{2} + 4 {CV}_{i n}^{3} + … )$$

The “Gain” of an ADC depends on two things. The Reference voltage V_{ref}, and the coefficients that represent its nonlinearity (A, B, C . . . ). For the “Gain” and linearity of two channels to match, both the reference and linearity coefficients desirably match. In the case of an interleaved perfectly linear (ideal) ADC, simply sharing the reference is sufficient to match the gain. This is a special case of this matching technique.

Ideally, the nonlinearity coefficients (A, B, C . . . ) are zero. However, in the case of a practical pipelined ADC, the linearity error is dictated by capacitor matching, gain and settling performance of the amplifiers and IR drops in the reference string and power grid. In an ideal pipelined ADC, all the stages have the same reference. In practice, this is not true due to IR drops in a practical physical layout. If the gain, settling performance, reference voltage and power grid of the adjacent channels match, the linearity will also match to the first order.

The stage gain and settling performance consists of two primary factors, the gain bandwidth of the op-amp (proportional to Transistor Ft) and the lithographic matching of the sampling and hold capacitors inside the pipelined ADC. This matching technique is more effective in modern process technologies where lithographic differences in the ADC capacitors are not the dominant factor in the linearity performance. This is the case for modern deep submicron processes. The paradigm shift here is that the ADC thermal noise level now sets the minimum sampling capacitor size. To reduce thermal noise, higher precision ADC's can use larger capacitors that have excellent matching in deep submicron processes. Improvements in lithography increase the benefit of this technique.

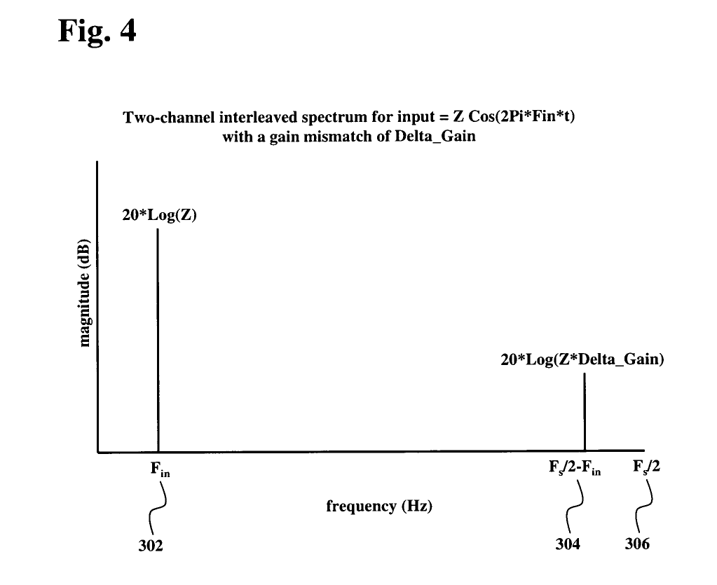

In reference to gain matching, for a N bit multi-channel ADC, the ADC channels' gain desirably matches to at least 1 part in 2^{N}. The error power of the gain mismatch is proportional to the magnitude of the difference in gain between the two channels. In the case of a two-channel ADC with a sine-wave input, the gain error appears as a tone Fₛ/2−Fᵢₙ where Fₛ is the sample rate of the ADC and Fᵢₙ is the frequency of the input sinewave. A two-channel interleaved ADC with a single tone-input has an output spectrum similar to FIG. 4.

FIG. 4 shows an example of an output spectrum for a two channel interleaved ADC. Shown are Fᵢₙ 302, Fₛ/2−Fᵢₙ 304, and Fₛ/2 306. Note: if Delta_Gain=0, then the output spectrum of the two-channel interleaved ADC is “ideal,” consisting of only a tone at Fᵢₙ.

Linearity mismatch error is similar but involves mixing of the harmonics with a tone at Fₛ/2. This is caused by mismatches between the coefficients (A, B, C . . . ) between the multiple ADC channels as discussed above. Mismatch between channel linearity gives tones at Fₛ/2−k*Fᵢₙ (where k=3, 4, 5, 6, 7 . . . ). If the linearity between the channels match, no extra tones are generated.

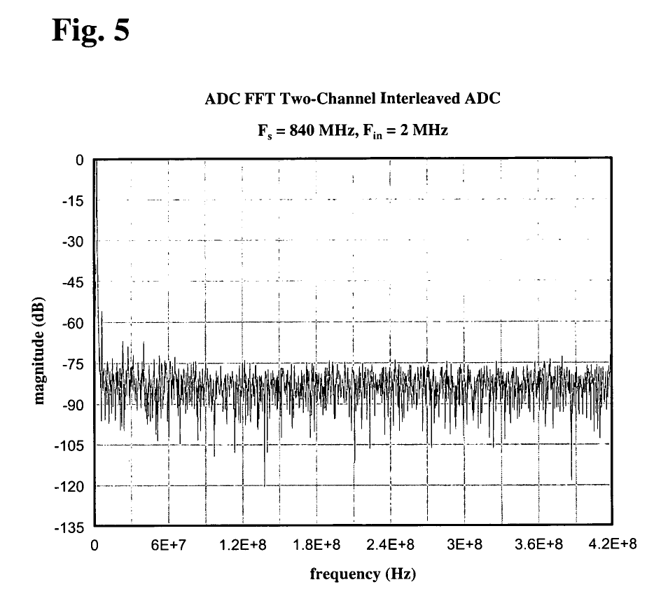

FIG. 5 shows an example of a collected data for a FFT of a time-interleaved ADC. FIG. 5 shows measured LAB data in the form of an FFT for a time-interleaved ADC using the techniques described here. The sample rate is 840 MHz. The input signal is at 2 Mhz. The spectrum shows the gain and phase mismatch tones constructively interfering at 418 Mhz. The mismatch tone is 72 dB below the fundamental and is not limiting the performance of the ADC. The linearity mismatch tones are 80 dB below the fundamental and are so weak that they are not visible in the figure. The excellent gain and linearity matching demonstrates the value of the technique presented in this application. This gain matching performance is comparable to or better than the prior art without the use of any digital post-processing of the ADC output data.

This channel matching is done by sharing ADC components such as the reference generator, reference distribution string, power-grid and the bias generator.

Since thermal noise dictates the size of the passive components in a sub-micron ADC, these relatively large capacitors match very well due to the advanced lithographic techniques employed. Thermal noise (kT/C) is independent of process and does not scale with lithographic feature size. The smaller voltages required for reliable operation in deep submicron processes require larger capacitors than were used in older processes. This large capacitor results in better matching since it is relatively large compared to the precision of the process lithography. As lithography technology improves, so will the precision of this technique.

An interleaved ADC using this technique requires less power and area when compared to the prior art since extra circuits (such as DACs and digital multipliers, for example) are not required to match the channels.

When the predominant mechanism of nonlinearity is dominated by transistor properties, then laying out the key performance limiting transistors in close proximity allows the nonlinearity of the ADC channels to match.

The multiple ADC channels need not be pipelined architecture. The same technique can be applied to other types of ADC's, as long as the clock, tree and reference generator are shared between the multiple ADC channels. The sharing technique can be applied to flash ADC's, algorithmic ADC's, two-step ADC's and Successive approximation ADC's to name a small subset. These ADC's will benefit from sharing analog resources such as references, power supplies and bias current generators.

It will be apparent to one skilled in the art that the described embodiments may be altered in many ways without departing from the spirit and scope of the invention. Accordingly, the scope of the invention should be determined by the following claims and their equivalents.

What is claimed is:

1. A time-interleaved multi-channel pipelined analog to digital converter, the converter having a sampling rate of F, the converter comprising:
a plurality of channels, the channels being N in quantity, the channels each having a sampling rate of F/N, each channel comprising a plurality of stages;
a shared voltage reference generator;
at least one reference voltage ladder;
a shared power grid;
a shared bias network;
an analog input; and
N digital channel outputs,

2. The converter of claim 1, where N=2.

3. The converter of claim 1, where each stage is connected to the at least one reference voltage ladder.

4. The converter of claim 3, where connections between the stages and the at least one reference voltage ladder are arranged such that gain and linearity matching between corresponding stages of the channels are maximized.

5. The converter of claim 3, where critical analog portions of the stages are placed as close as possible to each other in a circuit board layout in order to match their dynamic performance.

6. The converter of claim 1, where analog portions of the channel stages are in close proximity.

7. The converter of claim 1, where there is no analog calibration.

8. The converter of claim 1, where there is no background calibration.

9. The converter of claim 1, where there is no trimming.

10. The converter of claim 1, where there is no digital filtering.

11. The converter of claim 1, where the converter is manufactured using a submicron CMOS process.

12. The converter of claim 1, where the N digital channel outputs are time-interleaved to form a final digital output.

13. The converter of claim 1, where sampling and hold capacitors of corresponding channel stages are lithographically matched.
